(19) United States
(12) Patent Application Publication
(10) Pub. No.: US 2006/0221583 A1
(43) Pub. Date: Oct. 5, 2006

(54) Grounding structure of liquid crystal display and method thereof

(75) Inventor: I-Wen Su, Chiayi County (TW)

Correspondence Address: BIRCH STEWART KOLASCH & BIRCH, PO BOX 747, FALLS CHURCH, VA, 22040-0747, US

(73) Assignee: BENQ CORPORATION

(21) Appl. No.: 11/392,701

(22) Filed: Mar. 30, 2006

(30) Foreign Application Priority Data
Apr. 1, 2005 (TW) 94110463

(51) Int. Cl. H05K 5/00

(52) U.S. Cl. 361/753; 361/816

(57) ABSTRACT

A grounding structure for a liquid crystal display and method thereof. A ground metal spring is disposed on a shedding. A main structure and a print circuit board are detachably disposed on the shedding and respectively contact the ground metal spring. Therefore, the print circuit grounds to the main structure through the ground metal spring.

### BACKGROUND

The present invention relates to a grounding structure of a liquid crystal display and method thereof.

Grounding structures are essential in electrical devices. A conventional grounding structure employed in the liquid crystal display typically comprises a metal sheet disposed on the printed circuit board thereof. In assembly of the LCD, the metal sheet contacts to the main structure of the LCD. Since the main structure is made of metal, the printed circuit board is electrically connected to the main structure by the metal sheet to form the grounding structure.

FIG. 1 shows an example of the conventional grounding structure. A metal sheet 150 is disposed on the printed circuit board 20 of the LCD. The main structure 10 and the printed circuit board 20 are respectively disposed on the shedding of the LCD, and the metal sheet 150 are arranged to contact to the main structure 10. In order to maintain contact between the metal sheet 150 and the main structure 10, however, both the main structure 10 and the printed circuit board 20 must be positioned with precise accuracy. This increases difficulty in LCD assembly.

Further, the metal sheet 150 is disposed between the main structure 10 and the printed circuit board 20. It is possible in assembly that the metal sheet 150 collides or impacts to other elements in the LCD, and deformation thereof may occur, reducing the grounding stability.

### SUMMARY

In an embodiment of the invention, a grounding structure for a liquid crystal display comprises a shedding, a ground metal spring, a main structure, and a print circuit board. The ground metal spring is disposed on the shedding. The main structure and the print circuit are detachably disposed on the shedding and respectively contact the ground metal spring. Therefore, the print circuit grounds to the main structure through the ground metal spring.

In a further embodiment, a method of grounding for the liquid crystal display is disclosed. A shedding is provided. A ground metal spring is disposed on the shedding. A main structure and a print circuit board are respectively disposed on the shedding and contact to the ground metal spring. Thus, the print circuit board is electrically connected to the main structure by the grounding metal spring.

The ground metal spring may comprise a fixing portion and two end portions. The fixing portion can be fixed on the shedding. The end portions may respectively contact the main structure and the print circuit board. Preferably, the shedding can be insulated.

A detailed description is given in the following embodiments with reference to the accompanying drawings.

### DESCRIPTION OF THE DRAWINGS

The present invention can be more fully understood by reading the subsequent detailed description and examples with references made to the accompanying drawings, wherein:

FIG. 1 is a schematic view of a conventional grounding structure for a liquid crystal display;

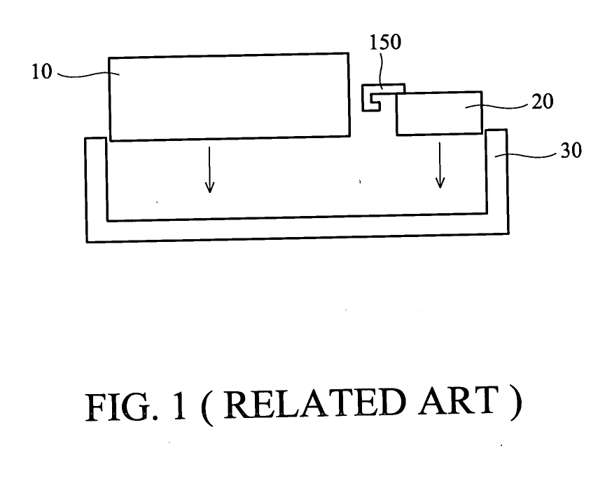

FIGS. 2a and 2b are a schematic views of an embodiment of the grounding structure for a liquid crystal display; and

FIG. 3 is a schematic view of the grounding metal spring 60 in FIG. 2b.

### DETAILED DESCRIPTION

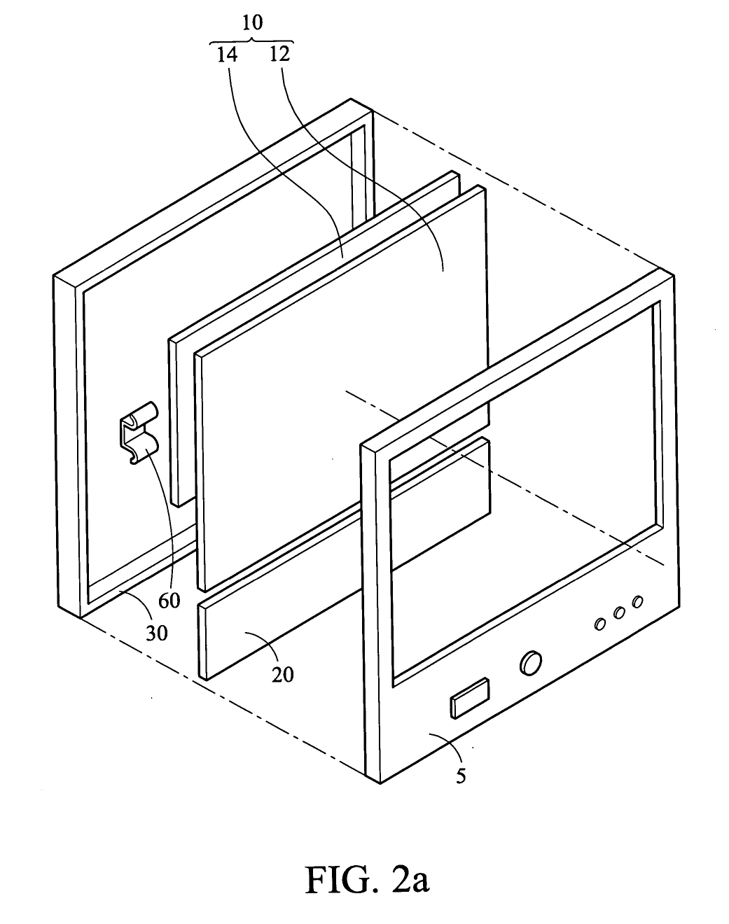

FIGS. 2a and 2b show an embodiment of a grounding structure for a liquid crystal display, comprising a front shield 5, a shedding 30, a ground metal spring 60, a main structure 10 and a print circuit board 20. The main structure comprises a panel 12 and a circuit board 14. Instead of being connected on the printed circuit board 20, the ground metal spring 60 is disposed on the shedding 30. Thus, when the main structure 10 and the print circuit board 20 are detachably disposed on the shedding 30, the main structure 10 and the print circuit board 20 respectively contact to the ground metal spring 60. Accordingly, the print circuit board 20 is electrically connected to the main structure 20 by the grounding metal spring 60.

In some embodiments, the shedding 30 can be insulated. In assembly of the grounding structure as shown in FIG. 2b, the ground metal spring 60 is disposed on the shedding 30. The main structure 10 and the print circuit 20 are respectively fixed on the shedding 30 and contact to the ground metal spring 60 such that the print circuit board 20 can be electrically connected to the main structure 20 by the grounding metal spring 60.

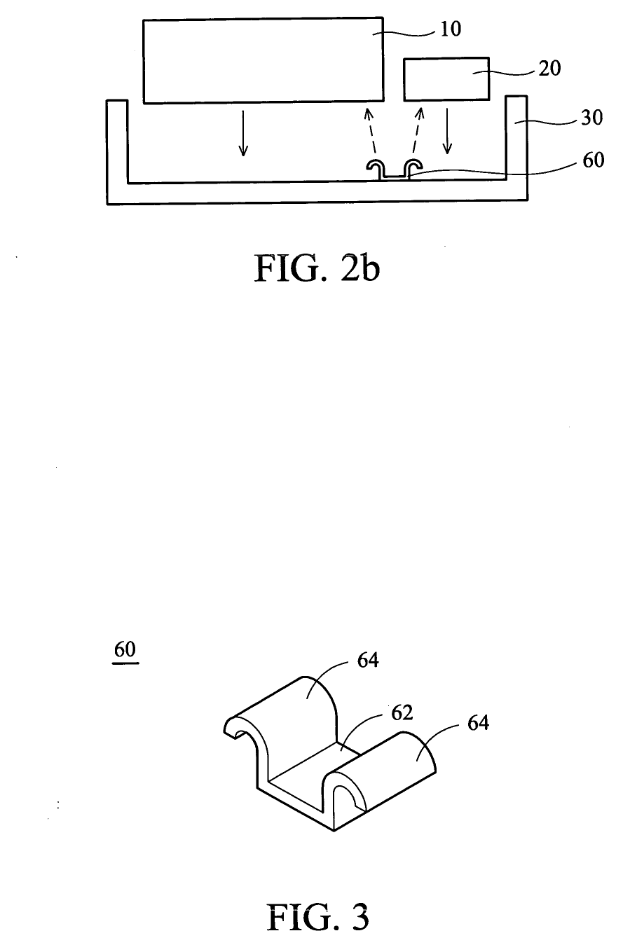

FIG. 3 shows a further embodiment of the grounding metal spring 60 in FIG. 2. In FIG. 3, the ground metal spring 60 comprises a fixing portion 62 and two end portions 64. The fixing portion 62 is a flat portion fixed on the shedding 30. The end portions 64 are arched portions and respectively contact the main structure 10 and the print circuit board 20. Shape and size of the fixing portion 62 and the end portions 64 can be preferably determined according to the size and element arrangement of the liquid crystal display.

In the embodiments, since the grounding metal spring 60 is directly disposed on the shedding 30, the size and shape thereof is not limited to the gap distance between the main structure 10 and the print circuit board 20. Accordingly, the main structure 10 and the print circuit board 20 can be disposed on the shedding 30 respectively and independently without requiring precise position accuracy.

In assembly of the grounding structure, the grounding metal spring 60 is disposed on the shedding 30 before the mounting process of the main structure 10 and the print circuit board 20. This greatly reduces the opportunity of collision or impact to the grounding metal spring 60 and prevents from deformation thereof, ensuring the grounding stability.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A grounding structure of a liquid crystal display, comprising:
a shedding;
a grounding metal spring disposed on the shedding;
a main structure detachably disposed on the shedding and contacting to the grounding metal spring; and
a printed circuit board detachably disposed on the shedding and contacting to the grounding metal spring for electrically connected to the main structure by the grounding metal spring.

2. The grounding structure as claimed in claim 1, wherein the grounding metal spring comprises a fixing portion and two end portions, the fixing portion fixed on the shedding, the end portions respectively contacting to the main structure and the printed circuit board.

3. The grounding structure as claimed in claim 1, wherein the shedding is insulated.

4. The grounding structure as claimed in claim 1, wherein the main structure comprises a panel and a circuit board, wherein the circuit board is disposed on the back side of the panel and contacts the grounding metal spring.

5. The grounding structure as claimed in claim 1 further comprising a front shield covering the main structure and the printed circuit board.

6. A method of grounding for a liquid crystal display, comprising the steps of:
providing a shedding;
disposing a grounding metal spring on the shedding;
disposing a main structure on the shedding, the main structure contacting to the grounding metal spring; and
disposing a printed circuit board on the shedding, the printed circuit board contacting to the grounding metal spring for electrically connected to the main structure by the grounding metal spring.

7. The method as claimed in claim 6, wherein the grounding metal spring comprises a fixing portion and two end portions, the fixing portion fixed on the shedding, the end portions respectively contacting to the main structure and the printed circuit board.
